(19) United States
(12) Patent Application Publication
(10) Pub. No.: US 2004/0090254 A1
(43) Pub. Date: May 13, 2004

(54) Systems and methods for altering timing edges of an input signal

(76) Inventors: Ronnie Edward Owens, Fort Collins, CO (US); Barbara J. Duffner, Fort Collins, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/292,971

(22) Filed: Nov. 13, 2002

(51) Int. Cl. H03K 5/12

(52) U.S. Cl. 327/170

(57) ABSTRACT

Systems for altering the timing of edges of an input signal for altering the position in time of timing edges of an input signal are disclosed. Such a system includes a differential amplifier having positive and negative inputs and outputs. The differential amplifier includes a symmetrical differential field effect transistor (FET) pair, each FET transistor of the pair having drain, source, and gate electrodes, wherein the source electrodes of the FET transistors are connected together. The differential amplifier also includes active loads coupled to the drain electrodes of the FET transistors and configured to be controllably biased to offset effects to the delay element caused by a plurality of operating variations. The delay element also includes variable capacitance banks connected to the outputs of the differential amplifier and configured to supply a selected capacitance to the outputs so as to delay and thereby alter the timing edges of the input signal. Methods and other systems also are provided.

### FIELD OF THE INVENTION

The present invention generally relates to variable delay circuits. More particularly, the present invention relates to systems and methods for altering timing edges of an input signal.

### DESCRIPTION OF THE RELATED ART

Many conventional discrete and gate array devices are used in the electronics industry for adjusting the phase of digital signals. Phase adjustment is typically accomplished by delaying the rising or falling edge of a digital pulse. However, due to power supply, temperature, and/or manufacturing process variations, the delays produced by these conventional devices may vary.

One such application in which inconsistent delay is unacceptable is in testing applications. By way of example, integrated circuits are typically tested by applying test signals to the circuits and then monitoring the outputs of the circuits. Clearly, the accuracy of the test signals is often critical so that an improper output can be attributed to the defects in the circuit and not to the test signal. Those variables listed above, such as temperature can degrade the accuracy of the test signals and lead to inaccurate test results.

Based on the foregoing, it should be understood that there is a need for improved systems and methods that address those and/or other perceived shortcomings of the prior art.

### SUMMARY OF THE INVENTION

A system in accordance with the invention for altering the position in time of timing edges of an input signal includes a differential amplifier having positive and negative inputs and outputs. The differential amplifier includes a symmetrical differential field effect transistor (FET) pair, each FET transistor of the pair having drain, source, and gate electrodes, wherein the source electrodes of the FET transistors are connected together. The differential amplifier also includes active loads coupled to the drain electrodes of the FET transistors and configured to be controllably biased to offset effects to the system caused by a plurality of operating variations. The system also includes variable capacitance bank connected to the outputs of the differential amplifier and configured to supply a selected capacitance to the outputs so as to delay and thereby alter the timing edges of the input signal.

The present invention may also be construed as a differential amplifier having positive and negative inputs and outputs. The differential amplifier includes a symmetrical differential field effect transistor (FET) pair, each having drain, source, and gate electrodes, wherein the source electrodes of the FET transistors are connected together and active loads coupled to the drain electrodes of the FET transistors and configured to be controllably biased to offset effects to the differential amplifier caused by a plurality of operating variations. The differential amplifier also includes a third FET transistor coupled to the source electrodes of the FET differential pair and configured as an active current source. The third FET transistor is configured to be selectively biased to control an amount of current passing through the third FET transistor so as to further offset effects to the differential amplifier caused by the plurality of operating variations.

A method in accordance with the present invention includes: providing an input signal and the compliment of the input signal to a delay element; varying a resistance of the delay element to offset effects caused by a plurality of operating variations; and varying a capacitance of the delay element to provide for a discrete delay to the input signal.

Clearly, some embodiments of the invention may address shortcomings of the prior art in addition to, or in lieu of, those described here. Additionally, other systems, methods, features, and advantages of the present invention will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

The invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a block diagram illustrating an embodiment of a testing system in accordance with the present invention.

FIG. 2 is a circuit schematic of an embodiment of a delay element in accordance with the present invention.

FIG. 3 is a circuit schematic of a variable capacitance an embodiment of the delay element of FIG. 2.

FIG. 4 is a flowchart diagram illustrating an embodiment of a method for altering timing edges of a signal in accordance with the present invention.

FIG. 5 is a flowchart further illustrating the method of FIG. 4.

FIG. 6 is a flowchart diagram illustrating another embodiment of a method for effectively altering timing edges of a signal using the embodiment of the delay element of FIG. 2.

### DETAILED DESCRIPTION

Systems and methods according to the present invention provide variable delays to input signals. As described in more detail below, the systems and methods may be able to more accurately provide such variable delays with regard to a variety of operating variations, such as temperature, supply voltage, and process variations than conventional systems.

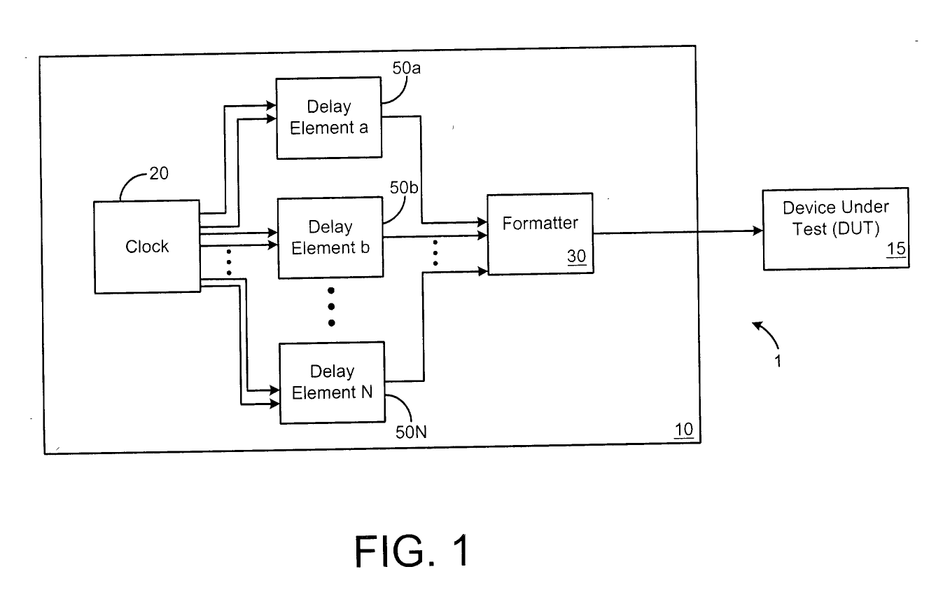

FIG. 1 is a block diagram illustrating an embodiment of a testing system 1 in accordance with the present invention. The testing system 1 generally includes a waveform generator 10 coupled to a device under test (DUT) 15. The DUT 15 may be any electrical component to which a test signal may be provided. For example, the DUT 15 of FIG. 1 is an integrated circuit (IC).

The waveform generator 10 includes a clock 20 coupled to N delay elements 50a-50N. The delay elements 50a-50N are collectively coupled to a formatter 30. The formatter 30 is depicted as being directly coupled to the DUT 15, although indirect coupling via other components could be used. In practice, the waveform generator 10 may include other components that may further shape and define a waveform such as gain stages, integrator circuits, and/or differentiating circuits. These elements may be used to create waveforms other than the standard waveform typically produced by the clock 20, such as triangle waveforms and ramp waveforms. Although, in practice, these components would be found in most waveform generators 10, they have been excluded from this explanation for clarity. Those skilled in the art would appreciate that the components described in FIG. 1 suffice for a concise explanation.

In practice, the clock 20 provides a clock signal to each of the delay elements 50a-50N, where the clock signal is typically a square wave with a particular period and amplitude. The clock signal generally provides for a symmetrical square wave. Testing with this symmetrical, pre-defined, periodic, square wave signal is limited. Manipulation of this signal may provide for more elaborate test signals.

In the embodiment of FIG. 1, 16 delay elements (N=16) 50a-50N receive the clock signal from the clock 20. In other embodiments, a different number of delay elements 50 is provided. Generally, each delay element 50 is pre-configured to provide for a different delay to the clock signal that is provided by the clock 20. It is important to note, aspects of the present invention require not only the clock signal to be provided to a delay element 50 but also the exact compliment (the inverse) of the clock signal. This may require a simple inverter to be placed in between the clock signal 20 and each of the delay elements 50a-50N. Alternatively, the clock 20 may produce an inverse to the clock signal concurrently with the clock signal. The importance of having a complimentary signal will become clear in later figures. Likewise, the structure and function of a delay element 50 will be described in later figures.

The formatter 30 may be considered a programmable function block that builds the waveform. The formatter 30 is configured to receive the output signals from each of the delay elements 50a-50N. Each output signal may be a different delayed representation of the original clock signal. Furthermore, although not shown, other functional blocks may be found between the delay elements 50a-50N and the formatter 30 such as gain amplifiers, inverters, etc. . The formatter 30 may be programmed to select certain signals from certain selected delay elements 50a-50N and thus provide one waveform to the DUT 15. The selected waveform is thus used as a stimulus signal to the DUT 15 to stimulate certain behaviors of the DUT 15.

The waveform generator 10 would typically be found in some type of automatic testing equipment (ATE). The ATE may include programmable inputs that may be provided to the delay elements 50a-50N to selectively control the delay provided by each element. Other inputs of the ATE may be provided to the formatter 30 to choose and piece together a single waveform from the collective delayed waveforms. ATEs are well known in the art and so no further explanation is provided.

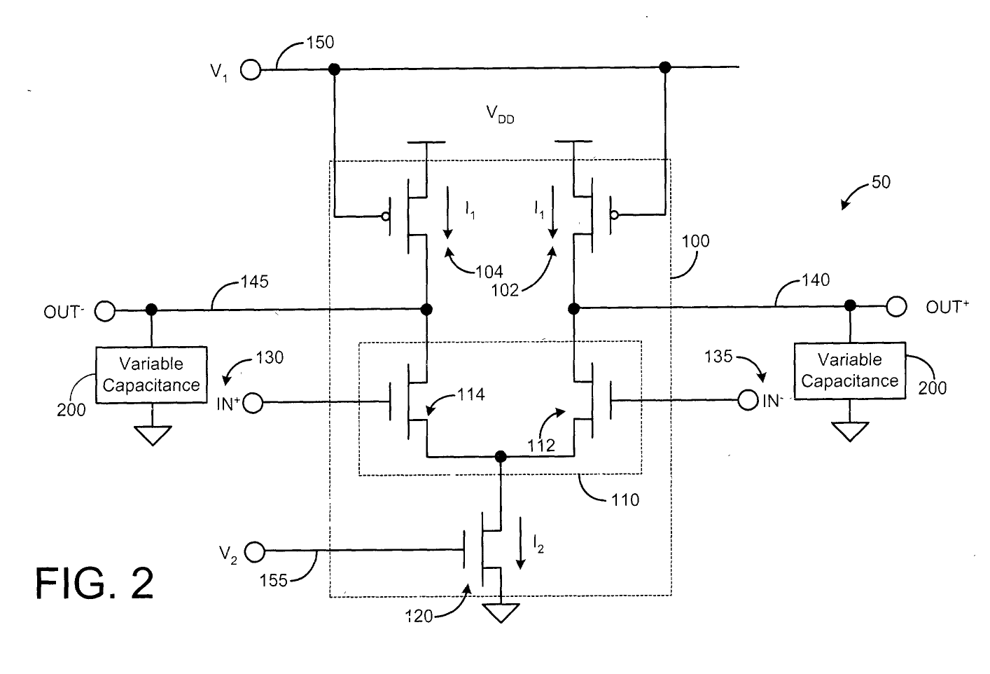

FIG. 2 is a circuit schematic of a delay element 50 in accordance with embodiments of the present invention. The delay element 50 may be considered any one of the delay elements 50a-50N of the waveform generator 10 of FIG. 1. The delay element 50 may provide for a predetermined constant delay to an input signal. The delay provided to the input signal may remain constant regardless of operating variations that would typically affect the delay provided to the input signal. Furthermore, the delay element 50 may be programmably configured during operation to provide a different delay.

The delay element 50 includes a differential amplifier 100 having a positive input (IN⁺) 130 and a complimentary negative input (IN⁻) 135. Likewise, the differential amplifier 100 has a positive output (OUT⁺) 140 and a complimentary negative output (OUT⁺) 145. The differential amplifier 100 includes a symmetrical differential field effect transistor (FET) pair 110 having field effect transistors 112 and 114. In this embodiment, the FET transistors 112 and 114 are be substantially matched so as to provide for symmetry in the differential amplifier 100. The required tolerance of transistor matching may be dictated by the application. Some applications use only every other edge, making the matching requirement much less important. Other applications may use each edge and require an accuracy in which transistor matching is more important. In these latter cases, a careful artwork realization may insure the matching is achieved to a sufficient tolerance. Otherwise, the matching is an intrinsic feature of the particular process technology used to implement the design in silicon. The design must be tolerant of this intrinsic transistor mismatch.

In this embodiment, the FET transistors 112 and 114 are NMOS transistors where the sources of the transistors 112 and 114 are tied together at a common node. The positive input 130 of the differential amplifier 100 is coupled to the gate of the FET transistor 114 and, likewise, the negative input 135 of the differential amplifier 100 is coupled to the gate of the second FET transistor 112 of the differential pair 110. Certainly, vice-versa could be applied. In this case, the outputs 140 and 145 would be switched. Again, this requires the differential amplifier 100 to be substantially balanced.

Two PMOS transistors 102 and 104 are coupled to the drains of the FET transistors 112 and 114 and serve to provide an active load on each side of the differential amplifier 100. In this embodiment, the active load PMOS transistors 102 and 104 are be biased in their linear region, thus serving as resistors. The sources of the active load FET transistors 102 and 104 are coupled to a supply voltage, V_{DD}. The positive output, OUT⁺, 140 is coupled to the drains of FET transistor 112 and active load transistor 102 which are coupled together. The negative output, OUT⁻, 145 of the differential amplifier 100 is coupled to the drains of FET transistor 114 and active load FET transistor 104.

A tail current source provided by a fifth FET transistor 120 may be coupled to the common sources of the symmetrical FET transistor pair 110. The FET transistor 120 may be biased such that it remains in its saturation region so as to serve as a tail current source to the differential amplifier 100.

A first control voltage, V₁, 150 is coupled to the gates of the active load FET transistors 104 and 102 to variably control the conductance of the active load FET transistors 104 and 102. The variance in the conductance of the FET transistors 104 and 102 can controllably vary the current I₁ passing through transistors 104 and 102 and on through to the outputs 140 and 145 of the differential amplifier 100.

A second control voltage, V₂, 155 may be provided to the gate of the tail FET transistor 120 to vary the conductance of the FET transistor 120. The variance in the conductance of the FET transistor 120 may vary the current 12 passing through the FET transistor 120.

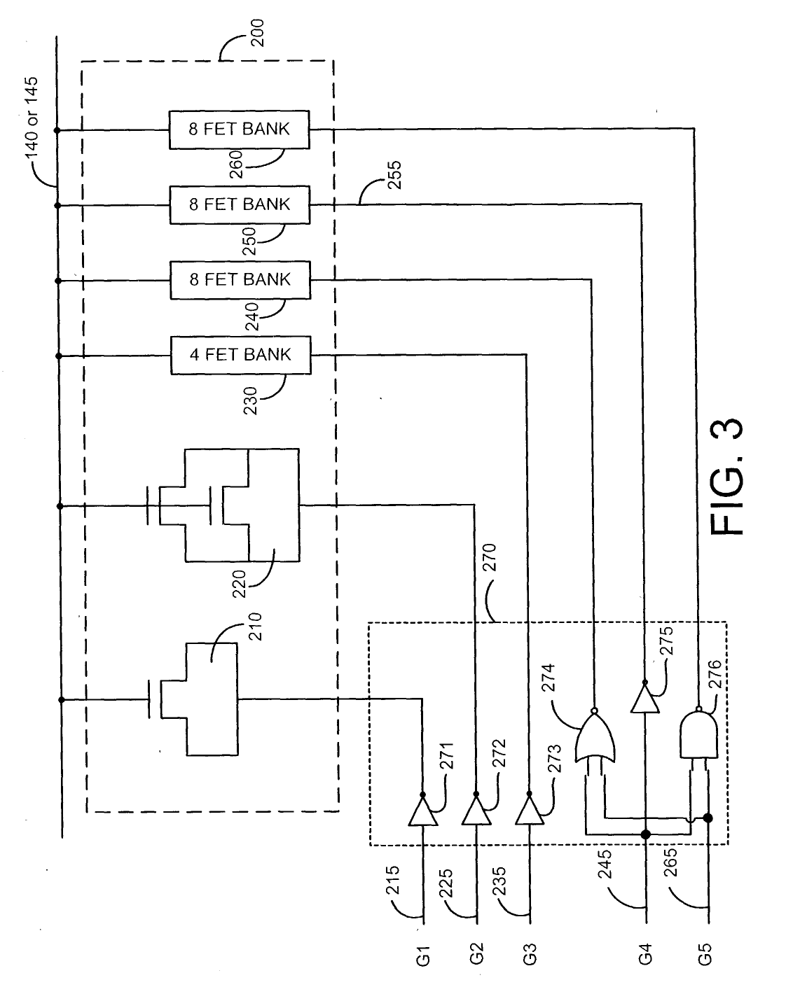

A variable capacitance bank 200 is coupled to each of the outputs 140 and 145 of the differential amplifier 100. The variable capacitance bank 200 will be described in further detail in FIG. 3, but generally is composed of several FET transistor banks that provide for incremental capacitance. The several FET transistor banks may be programmably enabled with a digital input signal.

Having described the general structure of the delay element 50, a description of the general operation of the delay element 50 will now be discussed. As mentioned above, the delay element 50 includes a differential amplifier 100. Like most differential amplifiers, this differential amplifier 100 has a positive 130 and negative input 135 as well as a positive 140 and negative output 145. It is preferred that the negative input 135 be the true and accurate compliment of the positive input 130. In general, the input signals 130 and 135 would be digital signals having sufficient amplitudes so that the differential amplifier 100 may have one transistor of the input pair 110 fully on and the other fully off. The input signals 130 and 135, however, should not be too great in amplitude, because this may cause the two PMOS FET transistors 102 and 104 to no longer operate in their linear regions. Ideally, an input signal would have an upper limit of the positive supply voltage, V_{DD}, and a lower limit of the positive supply voltage minus the threshold voltage (V_{DD}−V_{T}) of one of the NMOS FET transistors, either 112 or 114.

Assuming, a well balanced differential amplifier, the negative output 145 will be the compliment of the positive output 140. The differential input pair 110 may receive the differential inputs 130 and 135 via their respective gate electrodes. The differential outputs 140 and 145 of the differential amplifier 100 are coupled to the drain electrodes of the differential pair 110. The NMOS FET transistors 112 and 114 would be continually biased in their saturation regions despite the changing input signals 130 and 135.

The two PMOS FET transistors 102 and 104 are coupled to the drain electrodes of the transistors 112 and 114 and serve to act as active loads. The PMOS FET transistors 102 and 104 may be biased in their linear regions and so serve to act as variable resistances. The variable resistances of the PMOS FET transistors 102 and 104 are critical in controlling the operating point of the differential amplifier 100, in that they provide a controlled variable for the delay produced by amplifier 100. The PMOS FET transistors 102 and 104 may be biased with a first control voltage 150, V₁, through their respective gate electrodes. By continuously biasing the PMOS FETs 102 and 104, a constant current may be supplied to the outputs of the differential amplifiers 100.

A third NMOS FET transistor 120 may be coupled to the source electrodes of the NMOS FET transistors 112 and 114. The third NMOS FET transistor 120 may be continually biased in its saturation region so as to act as a controllable current source. A second control voltage 155, V₂, may be coupled to the gate electrode of the transistor 120 to continually bias the transistor 120. A common current source in the differential amplifier 100 greatly helps in balancing the two sides of the differential amplifier 100 and so helps in reducing an imbalance in the delay on the positive and negative timing edges (which can cause pulse-width modulation). The transistor 120 also helps in maintaining an operating current through the differential amplifier 100 that provides for a desired operating point of the differential amplifier 100, mainly in keeping the NMOS FET transistors 112 and 114 in saturation.

The two control voltages 150 and 155 may be provided by an external biasing circuit that can essentially offset operating variations on the differential amplifier 100. For example, temperature often can affect the performance of a FET transistor, and so the differential amplifier 100 is susceptible to temperature variations. In particular, the resistivity of the PMOS FET transistors 102 and 104 is subject to temperature variations, essentially because the carrier concentration of the devices are a strong function of temperature. The resistivity of the PMOS transistors 102 and 104 can also be controlled by the gate voltage, hence the first control voltage 150.

The supply voltage, V_{DD} may also vary and thus affect the performance of the differential amplifier 100. Keeping everything else constant, variations in V_{DD} can affect the current passing through the PMOS transistors 102 and 104 and on to the outputs of the differential amplifier 100. Worse yet, a drastic change in V_{DD} can take the PMOS transistors 102 and 104 out of the linear region. The first control voltage 150 with the second control voltage 155 helps in maintaining a constant current point throughout the differential amplifier 100 despite changes in the supply voltage, V_{DD}.

Process variations, another operating variation, can also affect the performance of the differential amplifier 100, and thus the performance of the delay element 50. Process variations may be considered variations in the physical aspects of the components of a circuit. For example, the width, W, and length, L, of any of the transistors of the differential amplifier 100 may be slightly different than their nominal values. This affects the behavior of the transistors at different operating points, but can be accounted for by the first and second control voltages 150 and 155.

Essentially, the delay on a signal induced by any amplifier is a subject of the amplifier's time constant, which is a function of its resistance and capacitance. The first control voltage 150, in particular, may be utilized to control a variable resistance (produced by the PMOS FET transistors 102 and 104) of the differential amplifier 100. The variable capacitance banks 200 on each of the outputs of the differential amplifier 100 are thus used to control the capacitance of the differential amplifier 100. The general operation of the variable capacitance banks 200 is discussed in further detail with reference to FIG. 3. In brief though, the variable capacitance banks 200 provide a stepwise capacitance to the differential amplifier 100 which can fine tune the desired delay on the signal. The variable capacitance banks 200 are also a function of the output current provided at, the drain electrodes of the PMOS and NMOS FET transistors. Control of the current at the drain electrodes is important in controlling the charge provided to the variable capacitances 200.

FIG. 3 is a circuit schematic of a variable capacitance bank 200 of the delay element 50 of FIG. 2. The variable capacitance bank 200 generally provides for a programmable capacitance which serves to provide a programmable delay to the signal. The variable capacitance bank 200 generally comprises several FET capacitor banks. The variable capacitance bank 200 is disclosed in U.S. Pat. No. 5,283,631 (issued Feb. 1, 1994) and incorporated by reference herein in its entirety.

A first capacitor bank 210 comprises one NMOS FET with its gate connected in parallel to the output signal line 140 or 145 (See FIG. 2) as well as a short-circuited source-drain node which is controlled by a gate-control input signal G1 on line 215 which is logically inverted and buffered by an inverter 271. The input signal G1 is the least significant bit (LSB) of the control word comprising input signals G1-G5. A gate-control input signal G2 on line 225 is inverted and buffered by an inverter 272 and controls the short-circuited source-drain node of a pair of parallel connected FETs forming the capacitor bank 220. The capacitor bank 220 is connected to the output signal line 140 or 145 so as to control the next significant bit on the output signal line 140 or 145. A gate-control input signal G3 on line 235, which is inverted by an inverter 273, controls a group of four FETs forming a capacitor bank 230, which is connected in parallel, via the gates of capacitor bank 230, to the output signal line 140 or 145 so as to control the next significant bit of the output signal line 140 or 145. A logical NOR 274 of a gate-control input signal G4 on line 245 and gate-control input signal G5 on line 265 controls the source-drain node of a capacitor bank 240, comprising eight NMOS FETs, that provide the next significant bit of delay to output signal line 140 or 145. An inverter 275 provides an inverted output signal 255 of the gate-control input signal G4. Output signal 255 controls the source-drain node of a capacitor bank 250, comprising eight NMOS FETs that provide a capacitance delay for the next significant bit on the output signal line 140 or 145. Gate-control input signals G4 and G5 are applied to respective inputs of a logical NAND 276. An output signal 267 of logical NAND 276 controls the source-drain node of a capacitor bank 260. The capacitor bank 260 comprises eight NMOS FETs that provide a capacitance delay for the MSB (Most Significant Bit) to output signal line 140 or 145.

Note that the FET of the first four capacitor banks are arranged in a binary fashion, (1, 2, 4, 8) so as to achieve the programmed capacitance capabilities offered by a binary decode provided to inputs G1 through G3. The two MSBs, G4 and G5, are decoded in a thermometer fashion such that capacitor bank 250 consists of eight NMOS FETs instead of the next binary equivalent of sixteen. The thermometer decode is such that the three 8 FET capacitor banks, 240, 250 and 260, turn on monotonically as the input signal G4 and the input signal G5 increase from a binary zero (00₂) to a binary three (11₂).

In practice, the programmable variable capacitance is obtained by modulating the gate-source-drain voltage (VGSS) of an NMOS FET where VGSS means gate-to-source voltage with drain shorted to source. The gate of the NMOS FET of each capacitor bank 210, 220, 230, 240, 250 and 260 is connected to the internal node of the buffer. The source and drain electrodes are shorted together. The gate capacitance is effectively switched in or out of the circuit by driving the source-drain node to the negative or positive supply voltage, respectively. Thus, small finely controlled amounts of capacitance can be added to the internal node via digital control. As is evident to those skilled in the art, the size of the capacitor FET is chosen corresponding to the fine timing resolution required by an application of the present invention. The number of capacitors attached to the internal node is determined by the dynamic range requirements. Since the delay of the element is linearly dependent on the capacitance of the internal node, this technique offers a linear relationship between the programmed capacitor setting and the delay of the circuit. For the present invention, the higher order capacitors are implemented as capacitor banks 240, 250, and 260 in order to reduce non-linearities.

The lower order capacitor banks 210, 220, and 230 (FET banks comprised of less than 8 FETs) are rendered active by control signals G1-G3. Once active, i.e., turned on, the transistors act like capacitors and sink charge from the output signal line 140 or 145 to thereby delay a signal propagating from the output of the differential amplifier 100. Control signals G1-G3 are Boolean coded to apply additional capacitance to the output signal line 140 or 145 in a linear fashion. The higher order bits (FET banks comprised of 8 or more FETs) are rendered active by control signals G4 and G5. The control signals G4 and G5 are thermometer encoded to minimize device mismatch due to process tolerances.

Collectively, the inverters 271, 272, 273, 275, NOR gate 274, and NAND gate 276 make up decode circuitry 270. The decode circuitry 270 may receive input control signals G1-G5 and subsequently drive the capacitor banks 210-260. BY controlling the capacitance of the capacitor banks 210-260 with the input control signals G1-G5, a precise control of the delay produced by the variable capacitance bank 200 may be achieved. This helps in fine tuning the timing edges of the output signal of the delay element 50.

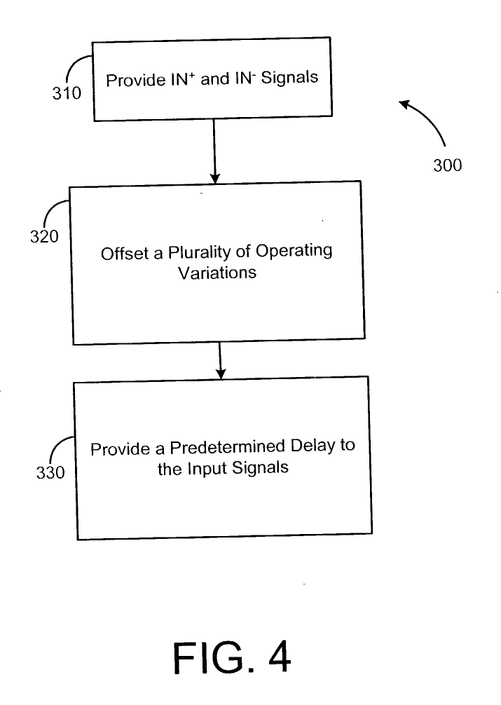

FIG. 4 is a flowchart diagram illustrating a general method 300 for altering timing edges of a signal in accordance with the present invention. The method 300 can be performed with a wide variety of circuit elements and devices. As will be discussed in subsequent flowcharts, the method will utilize components and elements similar to those discussed in relation to FIGS. 2 and 3.

With regard to all flowcharts described herein, each block represents a module, step, segment, or portion of the process. It should also be noted that in some alternate implementations, the functions noted in the blocks may occur out of the order depicted. For example, two blocks shown in succession may in fact be executed substantially concurrently, or the blocks may sometimes be executed in the reverse order, depending upon the functionality involved.

The method 300 begins with providing a positive and negative input signal (step 300). The method proceeds with offsetting a plurality of operating variations that can affect the manner in which the input signal is delayed (step 320). Offsetting the varying operating variations helps in maintaining a constant environment which is conducive for providing a predetermined delay to the signals (step 330). This predetermined delay may be of arbitrary resolution, but should be quite precise because of the constant operating environment created by step 320.

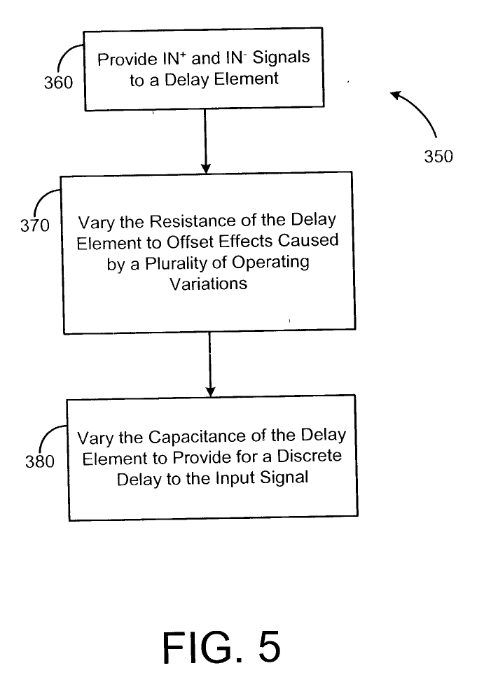

FIG. 5 is a flowchart diagram illustrating an embodiment of a method 350 for altering timing edges of a signal in accordance with embodiments of the present invention. The method 350 provides for a more detailed description of how a delay signal may be generated by embodiments of the present invention. The method 350 may be implemented by a number of different circuit and/or devices, but preferably by the delay element discussed in relation to FIG. 2. The method 350 can provide for a judiciously chosen delay that is both accurate and stable despite a variety of operating variations that can affect the performance of the particular circuitry performing the delay operation

The method 350 begins with providing a positive and negative input signal to a delay element (step 360). The input signals should be true compliments of each other and may be generated directly from a system clock because it helps in balancing the delay element.

The next step is to vary the resistance of the delay element to offset effects caused by a plurality of operating variations (step 370). These operating variations include: temperature variations; supply voltage variations; and/or process variations. Certainly other operating variations could affect the delay element as well. The resistance of the delay element provides for a first variable in controlling the delay provided by the delay element. Controlling the resistance helps in controlling the current provided to the outputs of the delay element.

The final step in the method 350 is to vary the capacitance of the delay element so as to provide for a discrete delay to the signal(s) passing through the delay element (step 380). The capacitance of the delay element, in this embodiment, is provided for by variable capacitances (See FIGS. 2 and 3) at the outputs of the delay element. Essentially, the capacitance of the delay element controls the rising times and falling times of the of the output signal as it changes from a low to a high state and from a high to a low state. The rising and falling times of the output signal determine the delay induced on the output signal. The variable capacitances as described in FIG. 3 can produce a delay with great precision, provided the charging current provided to the capacitances remains constant. A constant current may be maintained by controlling the resistance of the delay element.

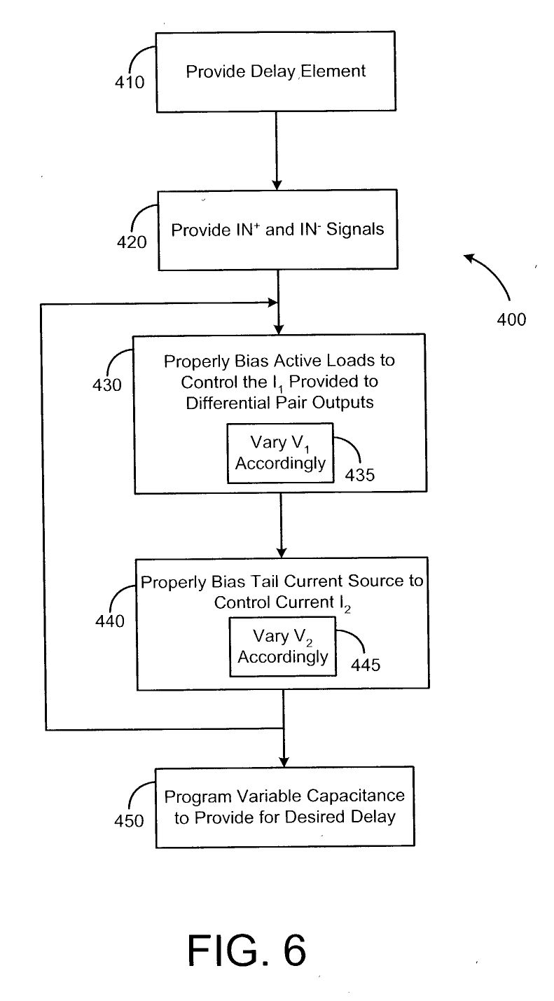

FIG. 6 is a flowchart diagram illustrating a method 400 for effectively and accurately altering the position in time of timing edges of a signal in accordance with embodiments of the present invention. The method 400 begins with providing a delay element configured to perform the delay operation (step 410). The delay element may be similar to delay element 50 of FIG. 2, where a differential amplifier is configured with variable capacitance outputs. The variable capacitance outputs may be programmed to provide a chosen delay to an input signal. The differential amplifier may include active loads and an active tail current source that may be continually biased to offset effects to the differential amplifier caused by operating variations. Examples of operating variations, as mentioned throughout, are temperature variation, supply voltage variation, and process variations to the components of the differential amplifier and variable capacitance. Other operating variations may exist and may be accounted for by the delay element 50.

The method 400 proceeds with providing an input signal and its compliment to the delay element, particularly to the positive and negative inputs of the differential amplifier of the delay element (step 420). Once an input signal is provided to the delay element, the active loads of the differential amplifier may be continuously biased to control the current provided to differential outputs of the differential amplifier. Controlling the current provided to the outputs of the differential amplifier controls the charging current that will be provided to the variable capacitances at the output of the differential amplifier. The charging current provided to the variable capacitances control the delay induced by the variable capacitances on the signal to be delayed. Biasing the active loads includes varying a bias voltage, V₁ (step 435), which may be provided to the gates of two PMOS FETs acting as the active loads. The two PMOS FETs may be biased in their linear regions and so they emulate resistances. Varying the bias voltage, V₁, can vary the resistance of the PMOS FETs, and thus vary the current passing through them. The bias voltage, V₁, may be judiciously varied and provided to the active loads by a biasing circuit that is configured to sense a plurality of process variations on the differential amplifier. For example, temperature can greatly vary the carrier concentration inside the PMOS FETs, which can vary the resistivity of the PMOS FETs. The bias voltage, V₁, can serve to offset the variation in resistivity induced by the variation in temperature. Essentially, the biasing circuit may effectively sense the temperature variation and produce the proper biasing voltage, V₁, to offset the sensed variation.

The method 400 proceeds with biasing the tail current source to control the current passing through it (step 440). In this embodiment, the tail current source is an NMOS FET that may be biased with a second biasing voltage, V₂, supplied to the gate of the NMOS FET. Varying V₂ is similar to varying V₁ to offset effects caused by various operating variations. Essentially, biasing V₁, and V₂ helps to keep a constant current environment in the differential amplifier. A constant current environment is critical to keeping the position of timing edges, and thus the delay in the signal, as constant and accurate as possible through varying operating conditions. Although step 440 appears after step 430 in FIG. 5, it should be appreciated that these steps may be performed concurrently. Properly biasing the active loads and the tail current source may be performed constantly throughout operation of the delay element.

The final step in method 400 is to program the variable capacitance to provide for a desired delay on the signal (step 450). This step has been discussed in detail in relation to FIG. 3. Programming the variable capacitance may be considered providing for a fine tuning of the timing edges, whereas biasing the active loads and the tail current source may be considered coarse tuning. In the former, the fine tuning may be performed to accomplish a precise delay on a signal. In the latter, the coarse tuning may be utilized to provide a desired delay that remains constant, particularly when operating variations affect the performance of the delay element.

The foregoing description has been presented for purposes of illustration and description. It is not intended to be exhaustive or to limit the invention to the precise forms disclosed. Modifications or variations are possible in light of the above teachings. The embodiment or embodiments discussed, however, were chosen and described to provide illustration of the principles of the invention and its practical application to thereby enable one of ordinary skill in the art to utilize the invention in various embodiments and with various modifications as are suited to the particular use contemplated.

By way of example, the methods described for programming the variable capacitance banks may have comparable alternatives. In another regard, the delay elements have been included in a waveform generator to provide an accurate programmable delay to a test waveform. Certainly, other utility may be found with the embodiments of the invention, in that they generally provide for an accurate selectable delay. In other words, an accurate alteration of the timing edges of a signal is provided. It should be appreciated by those skilled in the art that many applications for this type of element may be found. All such modifications and variations are within the scope of the invention as determined by the appended claims when interpreted in accordance with the breadth to which they are fairly and legally entitled.

1. A system for altering the timing of edges of an input signal, the system comprising:
a differential amplifier having positive and negative inputs and outputs, the differential amplifier comprising:
a symmetrical differential field effect transistor (FET) pair, each FET transistor of the pair having drain, source, and gate electrodes, wherein the source electrodes of the FET transistors are connected together; and
active loads coupled to the drain electrodes of the FET transistors and configured to be controllably biased to offset effects to the system caused by a plurality of operating variations; and
variable capacitance banks connected to the outputs of the differential amplifier and configured to supply a selected capacitance to the outputs so as to delay and thereby alter the timing edges of the input signal.

2. The system of claim 1, wherein the differential amplifier further comprises:
a third FET transistor coupled to the source electrodes of the FET differential pair and configured as an active current source, wherein the third FET transistor is configured to be selectively biased to control an amount of current passing through the third FET transistor so as to further offset effects to the system caused by the plurality of operating variations.

3. The system of claim 2, wherein a first biasing voltage is applied to the gate electrode of the third FET transistor so as to control a current passing through the third FET transistor.

4. The system of claim 2, wherein the plurality of operating variations includes any of the following: temperature variations, supply voltage variations, and process variations.

5. The system of claim 2, wherein the third FET transistor is an NMOS FET transistor.

6. The system of claim 1, wherein the plurality of operating variations includes any of the following: temperature variations, supply voltage variations, and process variations.

7. The system of claim 1, wherein the active loads of the differential amplifier each comprise:
a PMOS FET transistor having drain, source, and gate electrodes, wherein the drain electrode of the PMOS FET transistor of each active load is connected to the drain electrode of each of the FET transistors of the FET transistor pair.

8. The system of claim 7, wherein a second biasing voltage is applied to the gate electrode of the PMOS FET transistor of each active load so as to control a current passing through each of the PMOS FET transistors.

9. The system of claim 1, wherein the FET transistors of the FET transistor pair are NMOS FET transistors.

10. The system of claim 1, wherein the variable capacitance banks comprise:
decode circuitry for decoding an input control word into at least one control signal; and
at least one capacitor bank coupled to the decode circuitry and to an output of the differential amplifier for applying a finite amount of capacitance to the output of the differential amplifier as a function of the at least one control signal.

11. A differential amplifier having positive and negative inputs and outputs, the differential amplifier comprising:
a symmetrical differential field effect transistor (FET) pair, each having drain, source, and gate electrodes, wherein the source electrodes of the FET transistors are connected together;
active loads coupled to the drain electrodes of the FET transistors and configured to be controllably biased to offset effects to the differential amplifier caused by a plurality of operating variations; and
a third FET transistor coupled to the source electrodes of the FET differential pair and configured as an active current source, wherein the third FET transistor is configured to be selectively biased to control an amount of current passing through the third FET transistor so as to further offset effects to the differential amplifier caused by the plurality of operating variations.

12. The differential amplifier of claim 11, wherein the plurality of operating variations includes any of the following: temperature variations, supply voltage variations, and process variations.

13. The differential amplifier of claim 11, wherein the active loads each comprise:
a PMOS FET transistor having drain, source, and gate electrodes, wherein the drain electrode of the PMOS FET transistor of each active load is connected to the drain electrode of each of the FET transistors of the FET transistor pair.

14. The differential amplifier of claim 13, wherein a first biasing voltage is applied to the gate electrode of the PMOS FET transistor of each active load so as to control a current passing through each PMOS FET transistor.

15. The differential amplifier of claim 14, wherein the current passing through each PMOS FET transistor is controlled by the first biasing voltage controlling the resistivity of the PMOS FET transistors.

16. The differential amplifier of claim 11, wherein a second biasing voltage is applied to the gate electrode of the third FET transistor so as to control a current passing through the third FET transistor.

17. The differential amplifier of claim 16, wherein the third FET transistor is an NMOS FET transistor.

18. A method for altering the timing edges of an input signal, the method comprising:
providing an input signal and the compliment of the input signal to a delay element;
varying a resistance of the delay element to offset effects caused by a plurality of operating variations; and
varying a capacitance of the delay element to provide for a discrete delay to the input signal.

19. The method of claim 18, wherein the step of varying the resistance comprises:
properly biasing active loads of the delay element and a tail FET transistor of the delay element, wherein the tail FET transistor acts as a controlled current source.

20. The method of claim 19, wherein the active loads are PMOS FET transistors and wherein the step of properly biasing comprises:
providing a control voltage to the gate electrodes of the PMOS FET transistors such that control voltage controls the resistance of the transistors and thus the current flowing through the PMOS FET transistors.

21. The method of claim 18, wherein the plurality of operating variations includes any of the following: temperature variations, supply voltage variations, and process variations.
